(19) United States
(12) Patent Application Publication
(10) Pub. No.: US 2024/0410956 A1
(43) Pub. Date: Dec. 12, 2024

(54) LEAD-ACID STORAGE DEVICE, INFORMATION PROCESSING METHOD, AND COMPUTER PROGRAM

(71) Applicant: GS Yuasa International Ltd., Kyoto-shi, Kyoto (JP)

(72) Inventor: Yasuyuki HAMANO, Kyoto (JP)

(21) Appl. No.: 18/700,595

(22) PCT Filed: Jul. 8, 2022
(86) PCT No.: PCT/JP2022/027052

§ 371 Date: Apr. 11, 2024

(30) Foreign Application Priority Data
Oct. 14, 2021 (JP) 2021-169069

(51) Int. Cl. G01R 31/392; G01R 31/367; G01R 31/379; H01M 10/06; H01M 10/48

(52) U.S. Cl. CPC G01R 31/392; G01R 31/367; G01R 31/379; H01M 10/06; H01M 10/486; H01M 2220/20

(57) ABSTRACT

A lead-acid storage device includes a lead-acid battery and an estimation device. The estimation device includes an inventory information acquisition unit that acquires inventory information including an inventory period of the lead-acid battery, a storage that stores the inventory information acquired by the inventory information acquisition unit, and an estimation unit that estimates a degradation amount of the lead-acid battery based on the inventory information stored in the storage.

### TECHNICAL FIELD

The present invention relates to a lead-acid storage device, an information processing method, and a computer program.

### BACKGROUND ART

A lead-acid battery is used in applications such as on-board applications and industrial applications. For example, an on-board lead-acid battery is mounted on a vehicle, and supplies power to an on-board instrument such as lighting and a car stereo. The lead-acid battery is charged with power generated by a generator included in the vehicle.

It is known that degradation of the lead-acid battery progresses due to various factors. It is necessary to appropriately determine a degree of degradation in order to prevent stop of power supply due to unexpected loss of a function of the lead-acid battery.

Patent Literature 1 discloses a degradation diagnosis device that calculates an internal resistance based on current and voltage of the lead-acid battery mounted on the vehicle and determines the degradation based on the internal resistance.

### PRIOR ART DOCUMENT

### Patent Document

Patent Document 1: JP-A-2016-109639

### SUMMARY OF THE INVENTION

### Problems to be Solved by the Invention

The degradation diagnosis device described in Patent Literature 1 determines the degradation based on the internal resistance, and has a problem that degradation estimation accuracy is insufficient.

An object of the present disclosure is to provide a lead-acid storage device and the like capable of accurately estimating the degradation of the lead-acid battery.

### Means for Solving the Problems

A lead-acid storage device according to one aspect of the present disclosure includes a lead-acid battery and an estimation device. The estimation device includes an inventory information acquisition unit that acquires inventory information including an inventory period of the lead-acid battery, a storage that stores the inventory information acquired by the inventory information acquisition unit, and an estimation unit that estimates a degradation amount of the lead-acid battery based on the inventory information stored in the storage.

### BRIEF DESCRIPTION OF THE DRAWINGS

FIG. 1 is a perspective view illustrating a configuration example of a lead-acid storage device 1 according to an embodiment.

FIG. 2 is a sectional view taken along a line II-II of FIG. 1.

FIG. 3 is a block diagram illustrating a configuration example of an estimation device and the like of the lead-acid storage device.

FIG. 4 is a functional block diagram illustrating a configuration example of an estimation device.

FIG. 5 is a flowchart illustrating an example of a degradation amount estimation processing procedure in an inventory period.

FIG. 6 is a flowchart illustrating an example of an acquisition processing procedure of use start date and time.

FIG. 7 is a flowchart illustrating an example of the degradation amount estimation processing procedure in a use period.

### MODE FOR CARRYING OUT THE INVENTION

A lead-acid storage device according to one aspect of the present disclosure includes a lead-acid battery and an estimation device. The estimation device includes an inventory information acquisition unit that acquires inventory information including an inventory period of the lead-acid battery, a storage that stores the inventory information acquired by the inventory information acquisition unit, and an estimation unit that estimates a degradation amount of the lead-acid battery based on the inventory information stored in the storage.

According to the one aspect of the present disclosure, the estimation device can accurately estimate the degradation amount of the lead-acid battery using the inventory information including the inventory period of the lead-acid battery.

The inventory period may be a period from production completion to start of use of the lead-acid battery. For example, when the lead-acid battery is for a vehicle, the start of use of the lead-acid battery may be at a time point when the lead-acid battery is mounted on the vehicle.

The degradation amount may be a capacity retention ratio of the lead-acid battery or a full charge capacity. The capacity retention ratio is also referred to as State of Health (SOH), and is a ratio of the full charge capacity during the degradation to the initial full charge capacity of the lead-acid battery. Using the usable period as a reference, the degradation amount may be a proportion of a usable period remaining at the time point of evaluation.

In general, a life assumed for the lead-acid battery is shorter than that of other secondary batteries such as a lithium ion battery. For example, the life of the lead-acid battery mounted on the vehicle is usually about two to three years. For this reason, in the lead-acid battery, a proportion of the inventory period to the life of the battery increases. In the case of the battery having a long life such as the lithium ion battery, the inventory period such as several months has a small influence on life prediction, but in the case of the lead-acid battery, the inventory period has a large influence on the life prediction.

The inventory period of several months of the lead-acid battery greatly affects the accuracy of the life prediction because of the following reasons. The lead-acid battery self-discharges during the inventory period before use. The self discharge of the lead-acid battery progresses during the inventory period, so that an open circuit voltage (OCV) of the lead-acid battery gradually decreases from the initial OCV. During the first use of the lead-acid battery, State of Charge (SOC) corresponding to the OCV after the decrease is brought close to the control SOC suitable for the use of the lead-acid battery, so that a rapid charge reaction is likely to be generated.

The charge reaction of the lead-acid battery is a reaction of returning lead sulfate, which is a discharge product of a positive electrode and a negative electrode, to lead dioxide or spongy lead, and a sulfuric acid is generated at that time. The generated sulfuric acid temporarily increases a concentration of an electrolyte solution around an active material. Because specific gravity of the electrolyte solution having high concentration is greater than that of the surrounding electrolyte solution, the electrolyte solution settles down to the lower part of the battery due to gravity. As a result, a phenomenon (stratification) in which the concentration of the electrolyte solution increases in the lower part of the lead-acid battery and decreases in the upper part is generated. In the electrolyte solution having the high concentration of the sulfuric acid due to the stratification, coarsening of a lead sulfate crystal generally called sulfation and accumulation of the lead sulfate crystals are generated.

When the lead-acid battery is continuously used while the stratification of the lead-acid battery is generated, a discharge reaction is preferentially generated from a region having the high concentration of the sulfuric acid, and the degradation of the lead-acid battery locally proceeds. The local degradation increases a degradation rate with respect to the life of the lead-acid battery. From the above, a stratified degree, which is a phenomenon peculiar to the lead-acid battery during the inventory period, greatly affects the degradation of the lead-acid battery after the start of use. The inventory period greatly affects the accuracy of life prediction performed based on the degradation amount.

Because the lead-acid storage device of the present disclosure includes the estimation device, the inventory information including the inventory period from the production completion to the actual use start can be suitably detected. The estimation device can accurately estimate the degradation amount in consideration of the inventory information. Accordingly, the accuracy of life prediction can be improved.

In the lead-acid storage device, the estimation unit may estimate the degradation amount based on the self-discharge amount or the stratified degree estimated from the inventory information.

The self-discharge amount means a value indicating a self-discharge degree in the lead-acid battery, and for example, may be a self-discharge electricity quantity, or may be a self discharge rate or a self-discharge current. The stratified degree means a value indicating the stratified degree in the lead-acid battery.

According to the one aspect of the present disclosure, the estimation accuracy of the degradation amount can be improved by reflecting the self-discharge amount or the stratified degree of the lead-acid battery. As described above, the degradation amount of the lead-acid battery is greatly affected by the self-discharge amount or the stratified degree. The lead-acid storage device can estimate the self-discharge amount or the stratified degree according to the inventory period for each lead-acid battery by storing the inventory information using the estimation device. The lead-acid storage device can well estimate the degradation amount according to the inventory period of the lead-acid battery using the self-discharge amount or the stratified degree, which is the phenomenon peculiar to the lead-acid battery, for the estimation of the degradation amount.

In the lead-acid storage device, the inventory information may include a temperature related to the lead-acid battery in the inventory period, and the estimation unit may correct the self-discharge amount or the stratified degree based on the temperature related to the lead-acid battery in the inventory period.

According to the one aspect of the present disclosure, the temperature in the inventory period is further acquired, and the self-discharge amount or the stratified degree is corrected based on the acquired temperature. The self-discharge amount or the stratified degree of the lead-acid battery is related to a temperature state during the inventory period in addition to a length of the inventory period. The degradation amount more appropriately reflecting the inventory state of the lead-acid battery can be estimated by correcting the self-discharge amount or the stratified degree using the temperature in the inventory period.

The lead-acid storage device may include a use information acquisition unit that acquires use information including a use period of the lead-acid battery after start of use and a temperature related to the lead-acid battery during the use period, in which the storage stores the use information acquired by the use information acquisition unit, and the estimation unit estimates the degradation amount based on the use information.

According to the one aspect of the present disclosure, because the degradation amount can be estimated using the use information including a use history after the start of use in addition to the inventory information before the start of use of the lead-acid battery, the degradation amount at an arbitrary time point after the start of use can be suitably estimated. The degradation amount according to the state of the inventory period and the use period can be accurately estimated by taking into consideration the inventory information before the start of use.

In the lead-acid storage device, the estimation unit may predict the life of the lead-acid battery using the degradation amount.

According to the one aspect of the present disclosure, the life of the lead-acid battery can be accurately predicted on a lead-acid storage device side using the degradation amount estimated in accordance with an inventory status of the lead-acid battery. For example, as compared with the case where the life is predicted using only the use history after the start of use such as after mounting the vehicle, the accuracy of the life prediction can be improved using the degradation amount reflecting the state of the inventory period presented by the lead-acid storage device itself. In addition, the lead-acid storage device itself can present the life of the lead-acid battery by performing the life prediction on the lead-acid storage device side. In the life prediction of the lead-acid battery, intervention of a life prediction device (for example, a vehicle electronic control unit (ECU) on which a lead-acid storage device is mounted) is not required, and the work using the life prediction result, for example, inspection work of the lead-acid battery becomes easy.

The lead-acid storage device may include an output unit that outputs the degradation amount or the life of the lead-acid battery to an external device.

According to the one aspect of the present disclosure, the lead-acid storage device can transmit the estimated degradation amount and/or the predicted life of the lead-acid battery to the external device as needed. For example, the vehicle ECU can suitably control charge and discharge of the vehicle using the life of the lead-acid battery with high prediction accuracy received from the lead-acid storage device. Alternatively, the life prediction of the lead-acid battery can be accurately performed on a vehicle ECU side using the degradation amount transmitted from the lead-acid storage device. In addition, because the lead-acid storage device can transmit the degradation amount to the external device even during the inventory period or at the time of recycling after use, it is easy to determine whether or not to reuse the lead-acid battery 2 and a reuse method based on the degradation amount presented by the lead-acid storage device 1 during inventory storage or after removal from the target device.

The lead-acid storage device may be used for a vehicle. According to the one aspect of the present disclosure, because the lead-acid storage device can accurately estimate the degradation amount based on the inventory information, the lead-acid storage device can be suitably used for vehicles requiring high safety.

In an information processing method, a computer executes processing of acquiring inventory information including an inventory period of a lead-acid battery, storing the acquired inventory information, and estimating a degradation amount of the lead-acid battery based on the stored inventory information.

A computer program causes a computer to execute processing of acquiring inventory information including an inventory period of a lead-acid battery, storing the acquired inventory information, and estimating a degradation amount of the lead-acid battery based on the stored inventory information.

Hereinafter, the present invention will be specifically described with reference to the drawings illustrating an embodiment.

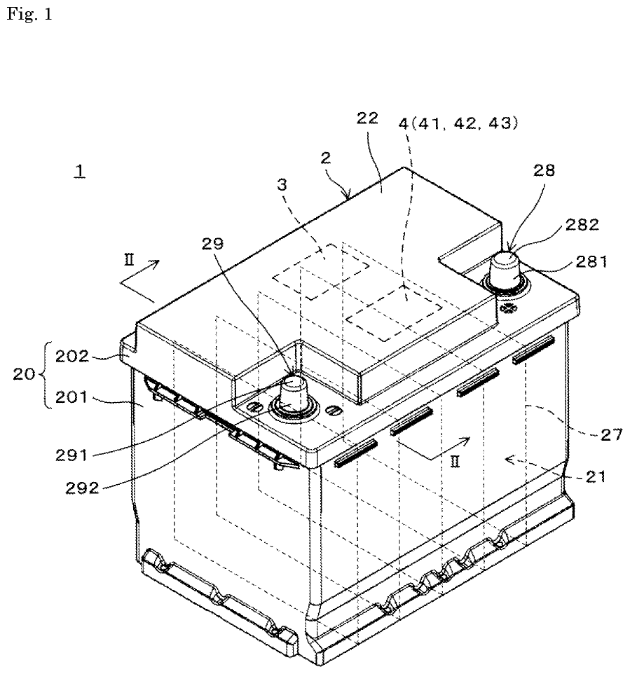

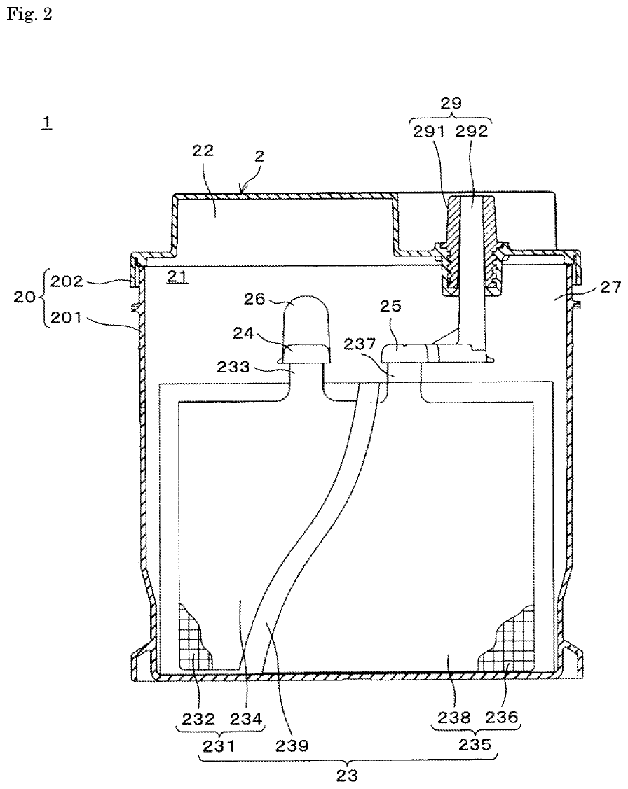

FIG. 1 is a perspective view illustrating a configuration example of a lead-acid storage device 1 according to an embodiment, and FIG. 2 is a sectional view taken along line II-II of FIG. 1. The lead-acid storage device 1 is for a vehicle such as an automobile or a forklift, and is installed in an engine room or a luggage space of the vehicle during use to supply power to an engine starter and various vehicle loads. The lead-acid storage device 1 includes a lead-acid battery 2 that stores the power, and an estimation device 3 that estimates a degradation amount of the lead-acid battery 2. As illustrated in FIGS. 1 and 2, the lead-acid battery 2 includes a container 20, a positive electrode terminal 28, a negative electrode terminal 29, and a plurality of elements 23.

The container 20 includes a container body 201 and a lid 202. The container body 201 is made of, for example, a synthetic resin, and is a rectangular parallelepiped case in which an upper portion is open. The lid 202 is made of, for example, a synthetic resin, and closes the opening of the container body 201. For example, a peripheral edge portion of a lower surface of the lid 202 and a peripheral edge portion of the opening of the container body 201 are joined by thermal welding. A space in the container 20 is partitioned by a partition 27 into a plurality of cell chambers 21 arranged in a longitudinal direction of the container 20.

A housing unit 22 is provided on an upper surface of the lid 202. The housing unit 22 has a box shape and protrudes outward at a central portion of one long side surface in a plan view. The housing unit 22 is covered with a cover, and houses the estimation device 3 and various sensors 4, which are flat circuit boards, therein. The estimation device 3 is connected to the lead-acid battery 2 and the various sensors 4 through a conductor (not illustrated) or the like.

In FIG. 1, the estimation device 3 is disposed in the housing unit 22 provided on the upper surface of the container 20. Alternatively, the disposition place may be a side surface of the container 20 or a lower surface of the container 20. A shape of the estimation device 3 is not limited to a flat plate shape.

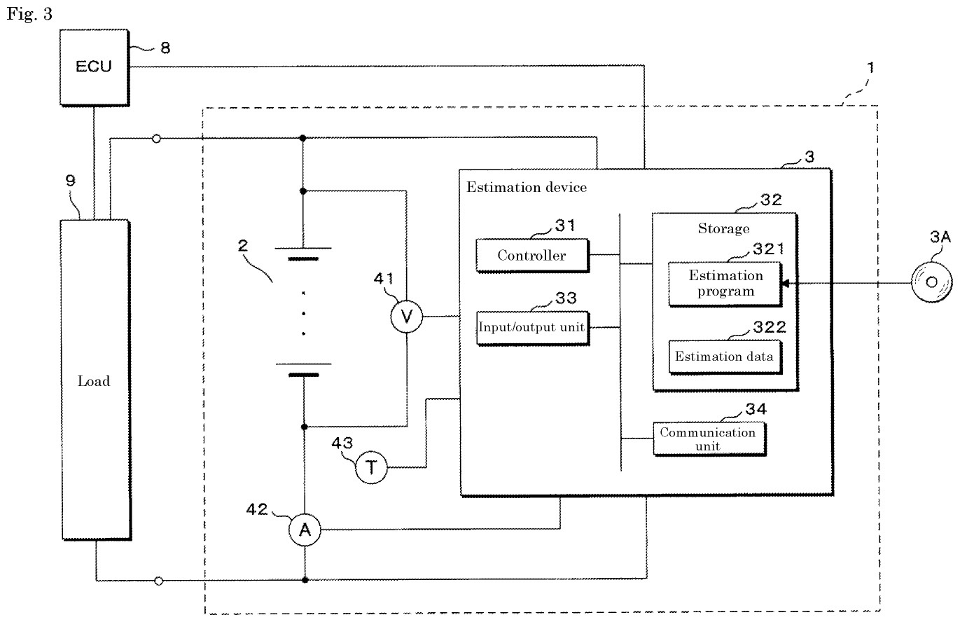

The sensor 4 included in the lead-acid storage device 1 includes a voltage sensor 41, a current sensor 42, and a temperature sensor 43 (see FIG. 3). The voltage sensor 41 is connected in parallel to the lead-acid battery 2 and measures an inter-terminal voltage of the lead-acid battery 2 in time series. The current sensor 42 is connected in series to the lead-acid battery 2 and measures current flowing through the lead-acid battery 2 in time series. For example, a current sensor that is not electrically connected to the lead-acid battery 2, such as a clamp current sensor, can also be used as the current sensor 42. The temperature sensor 43 is disposed near the lead-acid battery 2 and detects temperature related to the lead-acid battery 2. For example, the temperature related to the lead-acid battery 2 may be the temperature around an electrolyte solution of the lead-acid battery 2, the lead-acid battery 2, or the periphery of the lead-acid battery 2. A plurality of temperature sensors 43 may be provided. For the estimation of the degradation amount, it is preferable to use the temperature of the electrolyte solution of the lead acid battery 2 as the temperature of the lead-acid battery 2. Consequently, the temperature detected by the temperature sensor 43 may be corrected to be the temperature of the electrolyte solution according to a position where the temperature sensor 43 is disposed.

As illustrated in FIG. 2, one element 23 is housed in each cell chamber 21 in the container 20. The electrolyte solution (not illustrated) is housed in each cell chamber 21 in the container 20, and the entire element 23 is immersed in the electrolyte solution. The electrolyte solution is injected into the cell chamber 21 from an electrolyte solution filling port (not illustrated) provided in the lid 202. The electrolyte solution contains dilute sulfuric acid.

The element 23 includes a plurality of positive electrode plates 231, a plurality of negative electrode plates 235, and a separator 239. The plurality of positive electrode plates 231 and the plurality of negative electrode plates 235 are alternately arranged along an arrangement direction of the cell chambers 21.

The positive electrode plate 231 includes a positive electrode grid 232 and a positive electrode material 234 supported by the positive electrode grid 232. The positive electrode grid 232 is a conductive member including a bone arranged in a substantially grid shape or a net-like shape, and for example, is formed of lead or a lead alloy. The positive electrode grid 232 includes an ear 233 protruding upward near an upper end. The positive electrode material 234 contains lead dioxide as a main component. The positive electrode material 234 may further contain a known additive.

The negative electrode plate 235 includes a negative electrode grid 236 and a negative electrode material 238 supported by the negative electrode grid 236. The negative electrode grid 236 is the conductive member including the bone arranged in the substantially grid shape or the net-like shape, and for example, is formed of lead or a lead alloy. The negative electrode grid 236 includes an ear 237 protruding upward near the upper end. The negative electrode material 238 contains lead as a main component. The negative electrode material 238 may further contain a known additive.

For example, the separator 239 is formed of an insulating material such as glass or synthetic resin. The separator 239 is interposed between the positive electrode plate 231 and the negative electrode plate 235 that are adjacent to each other. The separator 239 may be configured as an integral member, or separately provided between the positive electrode plate 231 and the negative electrode plate 235. The separator 239 may be disposed so as to package either the positive electrode plate 231 or the negative electrode plate 235.

For example, the ears 233 of the plurality of positive electrode plates 231 are connected to a strap 24 formed of lead or a lead alloy. The plurality of positive electrode plates 231 are electrically connected in parallel through the straps 24. Similarly, for example, the ears 237 of the plurality of negative electrode plates 235 are connected to a strap 25 formed of lead or a lead alloy. The plurality of negative electrode plates 235 are electrically connected through the strap 25.

In the lead-acid battery 2, the strap 24 in one cell chamber 21 is connected to the strap 25 in one cell chamber 21 adjacent to the one cell chamber 21 through an intermediate pole 26 formed of, for example, lead or a lead alloy. The strap 25 in the one cell chamber 21 is connected to the strap 24 in the other cell chamber 21 adjacent to the one cell chamber 21 through the intermediate pole 26. That is, the plurality of elements 23 of the lead-acid battery 2 are electrically connected in series through the straps 24, 25 and the intermediate pole 26. The strap 25 housed in the cell chamber 21 located at one end in the longitudinal direction of the container 20 is connected not to the intermediate pole 26 but to a negative electrode pole 292 described later. The strap 24 housed in the cell chamber 21 located at the other end in the longitudinal direction of the container 20 is connected to not the intermediate pole 26 but a positive electrode pole (not illustrated).

The positive electrode terminal 28 is disposed at one end in the longitudinal direction of the container 20, and the negative electrode terminal 29 is disposed near the other end in the longitudinal direction of the container 20.

The negative electrode terminal 29 includes a bushing 291 and the negative electrode pole 292. The bushing 291 is a substantially cylindrical conductive member, and for example, is made of a lead alloy. A lower portion of the bushing 291 is integrated with the lid 202 by insert molding, and an upper portion of the bushing 291 protrudes upward from the upper surface of the lid 202. The negative electrode pole 292 is a substantially cylindrical conductive member, and is formed of, for example, a lead alloy. The negative electrode pole 292 is inserted into a hole of the bushing 291. The upper end of the negative electrode pole 292 is located at substantially the same position as the upper end of the bushing 291, and for example, joined to the bushing 291 by welding. The lower end of the negative electrode pole 292 protrudes downward from the lower end of the bushing 291, further protrudes downward from the lower surface of the lid 202, and is connected to the strap 25 housed in the cell chamber 21 located at one end in the longitudinal direction of the container 20. Similarly to the negative electrode terminal 29, the positive electrode terminal 28 includes a bushing 281 and a negative electrode pole 282 (see FIG. 1), and has the same configuration as the negative electrode terminal 29. When the lead-acid battery 2 is mounted on the vehicle, various vehicle instruments and the like are connected to the bushing 281 of the positive electrode terminal 28 and the bushing 291 of the negative electrode terminal 29.

FIG. 3 is a block diagram illustrating a configuration example of the estimation device 3 and the like of the lead-acid storage device 1. The lead-acid storage device 1 is mounted on the vehicle such as an automobile and used when using, for example, for the vehicle. The lead-acid storage device 1 includes the lead-acid battery 2 and the estimation device 3. The lead-acid storage device 1 is connected to a vehicle ECU 8, an engine starting starter motor, and a load 9 such as an electric component. When the starter motor functions as a generator, the lead-acid battery 2 is charged with the power (regenerative power) supplied from the starter motor. When the starter motor functions as a power source, the lead-acid battery 2 supplies the power to the starter motor and other electronic instruments.

The estimation device 3 acquires measured data including a voltage value, a current value, and a temperature of the lead-acid battery 2, and executes processing related to the estimation of the degradation amount of the lead-acid battery 2 based on the acquired measured data. For example, the estimation device 3 may be a battery management system (BMS). The estimation device 3 can be configured of one or a plurality of servers. The estimation device 3 may use a virtual machine as well as a plurality of devices for distributed processing. The estimation device 3 includes a controller 31, a storage 32, an input/output unit 33, a communication unit 34, and the like. The estimation device 3 operates using, for example, the power supplied from the lead-acid battery 2 connected to the estimation device 3. Alternatively, the estimation device 3 may include an external power supply such as a primary battery and operate using the power supplied from the external power supply.

The controller 31 is an arithmetic circuit including a central processing unit (CPU), a read only memory (ROM), a random access memory (RAM), and the like. The CPU included in the controller 31 executes various computer programs stored in the ROM or the storage 32 and controls the operation of each unit of the hardware described above, thereby causing the entire device to function as the estimation device of the present disclosure. The controller 31 may have functions such as a timer that measures an elapsed time from when a measurement start instruction is given to when a measurement end instruction is given, a counter that counts a number, and a clock that outputs date and time information. The controller 31 may be included in a vehicle, an external device, one or a plurality of servers, or the like.

The storage 32 is a nonvolatile storage device such as a flash memory. The storage 32 stores various computer programs and data. The computer program stored in the storage 32 includes an estimation program 321 that causes a computer to execute processing related to the estimation of the degradation amount of the lead-acid battery 2. The data stored in the storage 32 includes estimation data 322 used in the estimation program 321. For example, the estimation data 322 includes the inventory information on the inventory period from the production completion of the lead-acid battery 2 to mounting of the lead-acid battery 2 on the vehicle, the use information on the use period after mounting the lead-acid battery 2 on the vehicle, calculation data calculating the degradation amount using the inventory information and use information, and the like.

The computer program (computer program product) stored in the storage 32 may be provided by a non-transitory recording medium 3A on which the computer program is recorded in a readable manner. The recording medium 3A is a portable memory such as a CD-ROM, a USB memory, or a secure digital (SD) card. The controller 31 reads the desired computer program from the recording medium 3A using a reading device (not illustrated), and stores the read computer program in the storage 32. Alternatively, the computer program may be provided by communication. The estimation program 321 can be deployed to run on a single computer or on a plurality of computers located at one site or distributed across a plurality of sites and interconnected by a communication network. The storage 32 may be included in the vehicle, the external device, one or a plurality of servers, or the like.

The input/output unit 33 includes an input/output interface that connects the external device. The external device connected to the input/output unit 33 includes various sensors 4 such as the voltage sensor 41, the current sensor 42, and the temperature sensor 43. The input/output unit 33 receives input of signals related to measurement values measured by the various sensors 4. The controller 31 acquires the voltage, the current, and the temperature data as needed through the input/output unit 33.

A display device (not illustrated) may be connected to the input/output unit 33. An example of the display device is a liquid crystal display device. When the information on the degradation amount of the lead-acid battery 2 is obtained, the controller 31 outputs the information on the degradation amount of the lead-acid battery 2 from the input/output unit 33 to the display device. The display device displays the information on the degradation amount based on the information output from the input/output unit 33.

The communication unit 34 includes a communication interface that communicates with the external device (not illustrated). The communication unit 34 is communicably connected to the external device through a network such as the Internet. The external device communicably connected to the communication unit 34 is a terminal device such as a personal computer or a smartphone used by a user, an administrator, or the like. The controller 31 transmits the information on the degradation amount of the lead-acid battery 2 from the communication unit 34 to the external device. The communication unit 34 may include a communication interface that communicates with the vehicle ECU 8. For example, the communication unit 34 may be a communication interface based on a controller area network (CAN) protocol. The controller 31 transmits the information on the degradation amount of the lead-acid battery 2 from the communication unit 34 to the vehicle ECU. The estimation device 3 may include a notification unit such as an LED lamp or a buzzer in order to notify the user of the information on the degradation amount of the lead-acid battery 2.

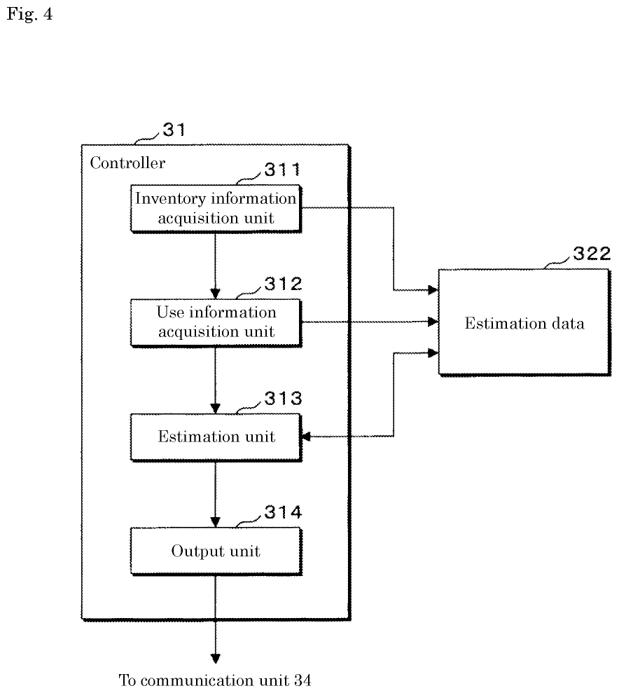

FIG. 4 is a functional block diagram illustrating a configuration example of the estimation device 3. The controller 31 of the estimation device 3 functions as an inventory information acquisition unit 311, a use information acquisition unit 312, an estimation unit 313, and an output unit 314 by reading and executing the estimation program 321 stored in the storage 32. In the embodiment, each of these functions is implemented by the controller 31 executing the estimation program 321. However, a part of these functions may be implemented by a dedicated hardware circuit, or each function may be shared by a plurality of functions. For example, the use information acquisition unit 312 and/or the estimation unit 313 may be plural. For example, the estimation device 3 may be configured in the vehicle, the external device, or the like, or included by one or a plurality of servers. In this case, for example, the controller 31 may acquire various types of measured data by receiving the measured data transmitted from the device or the like included in the lead acid battery 2 through the communication unit 34.

The inventory information acquisition unit 311 acquires the inventory information on the inventory period from the production completion to the start of use of the lead-acid battery 2. For example, the inventory information may include the inventory period (elapsed period from the production completion) and the measured data of the lead-acid battery 2 in the inventory period.

The inventory period may be a period from the production completion time (production completion date and time) to the start of use (use start date and time) of the lead-acid battery 2. For example, the production completion date and time of the lead-acid battery 2 is stored in the storage 32 of the lead-acid battery 2 at a manufacturing stage. The inventory information acquisition unit 311 starts counting of the inventory period from the time point when the production completion date and time is acquired. After starting to count the inventory period, the inventory information acquisition unit 311 acquires the voltage value, the current value, and the temperature of the lead-acid battery 2 measured by the voltage sensor 41, the current sensor 42, and the temperature sensor 43 at predetermined intervals. The inventory information acquisition unit 311 stores the acquired voltage value, current value, and temperature in the estimation data 322 of the storage 32 in association with the inventory period.

The use information acquisition unit 312 acquires the use information on the use period from the start of use of the lead-acid battery 2 to each time point after use. For example, the use information may include the use period (the elapsed period from the start of use), the measured data of the lead-acid battery 2 during the use period, and an internal resistance.

The use information acquisition unit 312 specifies a time point at which the lead-acid battery 2 satisfies the use start condition as the use start date and time. As the use start condition, for example, an absolute value of the current value of the lead-acid battery 2 may be greater than or equal to a predetermined value. When the current greater than or equal to the predetermined value is applied to the lead-acid battery 2, it is determined that the use of the lead-acid battery 2 has been started. Using the specified use start date and time as a reference, the use information acquisition unit 312 starts to count a period after the start of use date and time, namely, the use period. The use information acquisition unit 312 acquires the voltage value, the current value, and the temperature of the lead-acid battery 2 measured by the voltage sensor 41, the current sensor 42, and the temperature sensor 43 at predetermined intervals after starting to count the use period. The use information acquisition unit 312 stores the acquired voltage value, current value, and temperature in the estimation data 322 of the storage 32 in association with the use period.

The estimation unit 313 estimates the degradation amount of the lead-acid battery 2 during the inventory period or the use period based on the inventory information and the use information stored in the storage 32. Specifically, the estimation unit 313 estimates the self-discharge amount according to the inventory period of the lead-acid battery 2 based on the inventory information, and estimates the degradation amount using the estimated self-discharge amount.

The estimation unit 313 calculates the self-discharge amount based on a length of the inventory period using a correspondence relationship between the inventory period and the self-discharge amount, the correspondence relationship being previously stored in the storage 32. The correspondence relationship between the inventory period and the self-discharge amount is set such that the self-discharge amount increases as the inventory period becomes longer. The estimation unit 313 may calculate the self-discharge amount in consideration of the current value and the voltage value during the inventory period.

Furthermore, the estimation unit 313 corrects the calculated self-discharge amount according to a temperature change amount of the lead-acid battery 2 using the correspondence relationship between the temperature change and the self-discharge amount, the correspondence relationship being previously stored in the storage 32. The correspondence relationship between the temperature change amount and the self-discharge amount is set such that the larger the temperature change amount of the lead-acid battery 2 is, the larger the self-discharge amount is. The estimation unit 313 may calculate an average value of the temperature data of the lead-acid battery 2 measured by the temperature sensor 43, obtain a difference between the calculated average value and each measured value, and use the obtained difference as the temperature change amount. Because the self-discharge amount is not necessarily the same in the positive and negative electrodes, the self-discharge amount may be set in each of the positive and negative electrodes, or the average value of the positive and negative electrodes may be set.

The estimation unit 313 estimates the degradation amount based on the estimated self-discharge amount using the correspondence relationship between the self-discharge amount and the degradation amount, the correspondence relationship being previously stored in the storage 32. The correspondence relationship between the self-discharge amount and the degradation amount is set such that the larger the self-discharge amount is, the larger the degradation amount is. The estimation unit 313 stores a coefficient set according to the self-discharge amount in the estimation data 322 of the storage 32.

In estimating the degradation amount, the estimation unit 313 first acquires an initial degradation amount that does not consider the self-discharge amount at an arbitrary time point during the inventory period. For example, the initial degradation amount of the lead-acid battery 2 may be used as the initial degradation amount, the initial degradation amount being previously stored in the storage 32. The estimation unit 313 calculates a pre-use degradation amount at an arbitrary time point in the inventory period by multiplying the acquired initial degradation amount by the coefficient corresponding to the self-discharge amount at the arbitrary time point in the inventory period. The pre-use degradation amount is a degradation amount in consideration of the self-discharge amount during the inventory period. The pre-use degradation amount at the last time point of the inventory period corresponds to the pre-use degradation amount start, namely, at the time of first use.

The estimation unit 313 may estimate a stratified degree based on the self-discharge amount using the correspondence relationship between the self-discharge amount and the stratified degree, the correspondence relationship being previously stored in the storage 32. For example, the stratified degree is divided into five stages, and shows that the larger a numerical value is, the more the stratification progresses. The correspondence relationship between the self-discharge amount and the stratified degree is set such that the larger the self-discharge amount is, the larger the stratified degree is. The estimation unit 313 may estimate the corrected degradation amount based on the estimated stratified degree using the previously-stored correspondence relationship between the stratified degree and the correction value of the degradation amount. The correction value of the degradation amount is set such that the corrected degradation amount increases as the stratified degree increases.

The estimation unit 313 may correct the above-described degradation amount or stratified degree using the charge current value of the lead-acid battery 2 at the start of use or immediately after the start of use. The estimation unit 313 corrects the degradation amount or the stratified degree such that the larger the charge current value of the lead-acid battery 2 is at the start of use or immediately after the start of use, the larger the degradation amount or the stratified degree is.

The estimation unit 313 also estimates the degradation amount at an arbitrary time point after the start of use. The estimation unit 313 first calculates the degradation amount without considering the self-discharge amount at the arbitrary time point after the start of use. For example, the estimation unit 313 may sequentially calculate the degradation amount by a mathematical model using actual measured data of a use history of the lead-acid battery 2. The use history includes the current value, the voltage value, the internal resistance, the temperature, the use time, and the like. The internal resistance of the lead-acid battery 2 may be previously stored in the storage 32. Furthermore, the estimation unit 313 calculates the final degradation amount by adding the degradation amount at the time of the first use to the calculated degradation amount after the start of use. The estimation unit 313 may calculate the final degradation amount by adding or multiplying the degradation amount at the time of the first use to or by the degradation amount after the start of use.

The estimation unit 313 predicts a life of the lead-acid battery 2 based on the calculated degradation amount. For example, the estimation unit 313 can calculate the life from the calculated degradation amount using a relational expression between the degradation amount and the battery capacity of the lead-acid battery, the relational expression being previously obtained by computer simulation. The estimation unit 313 predicts the life of the lead-acid battery 2 using a battery capacity in consideration of the degradation amount of the lead-acid battery 2. The predicted life may be a high-rate discharge performance as well as the battery capacity. The life prediction technique is not limited, but a known prediction technique may be used. The estimation unit 313 may estimate State of Charge (SOC) or State of Health (SOH) of the lead-acid battery 2 based on the calculated degradation amount.

The output unit 314 outputs the degradation amount, the life prediction result, and the like received from the estimation unit 313 to the external device through the communication unit 34. For example, when the external device is the vehicle ECU 8, the vehicle ECU 8 receives the degradation amount transmitted from the lead-acid storage device 1, and can accurately predict the life of the lead-acid battery 2, estimate the charge state, derive the control condition related to the charge-discharge, and the like using the received degradation amount.

As described above, the lead-acid storage device 1 collects and manages the inventory information on the lead-acid battery 2 using the estimation device 3, thereby accurately estimating the degradation amount according to the inventory state of the lead-acid battery 2. Also regarding the degradation amount after the start of use, the estimation accuracy of the degradation amount can be improved by reflecting the pre-use degradation amount according to the inventory period.

In the above specification, the lead-acid battery 2 includes the estimation device 3. Alternatively, for example, the estimation device 3 may be configured in the vehicle, the external device, or the like, or included in one or a plurality of servers. In this case, for example, the controller 31 may acquire various types of measured data by receiving the measured data transmitted from the device or the like included in the lead-acid battery 2 through the communication unit 34.

A part of each configuration of the estimation device 3 described above may be included in the vehicle, the external device, one or a plurality of servers, or the like.

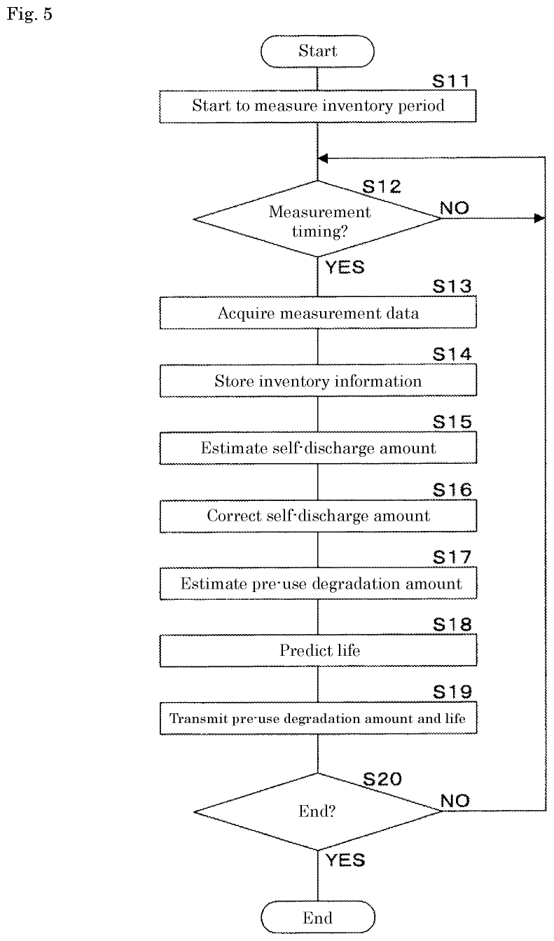

FIG. 5 is a flowchart illustrating an example of the degradation amount estimation processing procedure in the inventory period. The controller 31 of the estimation device 3 executes the following processing according to the estimation program 321.

The controller 31 acquires a production completion date and time of the lead acid battery 2, and starts to count (acquire) the elapsed period from the acquired production completion date and time, namely, the inventory period (step S11). For example, the production completion date and time is acquired by being written in a manufacturing stage, and stored in the storage 32 of the lead acid battery 2.

The controller 31 determines whether or not it is measurement timing (step S12). Specifically, the controller 31 determines whether or not the measured data output from the various sensors 4 is acquired through the input/output unit 33. When it is determined that it is not the measurement timing (NO in step S12), the controller 31 waits until the measurement timing.

When it is determined that it is the measurement timing (YES in step S12), the controller 31 acquires the measured data including the temperature, the voltage value, and the current value of the lead-acid battery 2 through the input/output unit 33 (step S13). The temperature, the voltage value, and the current value of the lead-acid battery 2 are measurement values measured in time series by the temperature sensor 43, the voltage sensor 41, and the current sensor 42, respectively. The controller 31 may acquire the measured data according to the output of the measured data by the various sensors 4 each time the new measured data is output from the various sensors 4 without determining whether or not it is the measurement timing.

In the above specification, the temperature, the voltage value, and the current value of the lead-acid battery 2 are collectively acquired. Alternatively, the measurement and acquisition timing of the temperature, the voltage value, and the current value may be different from each other. The controller 31 may acquire various types of measured data by receiving the measured data transmitted from the external device or the like through the communication unit 34.

The controller 31 stores the acquired measured data including the temperature, the voltage value, and the current value of the lead-acid battery 2 and the inventory period derived from the measured date and time of the measured data in the estimation data 322 of the storage 32 as the inventory information while being associated with each other (step S14).

The controller 31 estimates the self-discharge amount of the lead-acid battery 2 based on the stored inventory information (step S15). The controller 31 calculates the self-discharge amount based on the length of the inventory period using the correspondence relationship between the inventory period and the self-discharge amount, the correspondence relationship being previously stored.

The controller 31 corrects the calculated self-discharge amount based on the temperature change amount during the inventory period of the lead-acid battery 2 using the correspondence relationship between the temperature change amount and the self-discharge amount, the correspondence relationship being previously stored (step S16), and obtains the final self-discharge amount.

The controller 31 estimates the pre-use degradation amount at an arbitrary time point during the inventory period based on the estimated final self-discharge amount (step S17). The controller 31 calculates the initial degradation amount that does not consider the self-discharge amount. The controller 31 calculates the pre-use degradation amount by multiplying the calculated initial degradation amount by the coefficient corresponding to the estimated self-discharge amount. The controller 31 stores the calculated pre-use degradation amount in the storage 32.

The controller 31 predicts the life of the lead-acid battery 2 based on the calculated degradation amount (step S18). The processing of the life prediction in step S18 may be omitted. The controller 31 transmits the estimated pre-use degradation amount and/or the predicted life of the lead-acid battery 2 to the external device (step S19).

The controller 31 determines whether or not to end (step S20). For example, the controller 31 may determine that the use of the lead-acid battery 2 is ended by determining that the use of the lead-acid battery 2 is started by use start determination processing described later.

When determining not to end the processing (NO in step S20), the controller 31 returns the processing to step S12 and continues the estimation of the degradation amount. When determining to end the processing (YES in step S20), the controller 31 ends the series of processing.

In the above specification, the degradation amount was estimated based on the self-discharge amount. Alternatively, the controller 31 may estimate the degradation amount of the lead-acid battery 2 based on the stratified degree. In this case, the controller 31 specifies the stratified degree of the lead-acid battery 2 based on the final self-discharge amount obtained in step S16 using the correspondence relationship between the self-discharge amount and the stratified degree, the correspondence relationship being previously stored. The controller 31 may specify the stratified degree of the lead-acid battery 2 based on the self-discharge amount before reflection of the change amount of the temperature, and correct the specified stratified degree according to the change amount of the temperature. The controller 31 calculates the initial degradation amount that does not consider the stratified degree. The controller 31 calculates the pre-use degradation amount at an arbitrary time point during the inventory period by adding the correction amount corresponding to the estimated stratified degree to the calculated initial degradation amount.

According to the above-described processing, the degradation amount at an arbitrary time point during the inventory period is estimated as needed. In the above-described processing, the controller 31 may estimate the degradation amount at that time every time the measured data is acquired from the input/output unit 33, or may estimate the degradation amount at each time point by sequentially reading the measured data from the storage 32 after storing the measured data for a certain period in the storage 32. The controller 31 may estimate the degradation amount for the first time when it is determined that the use of the lead-acid battery 2 is started by the use start determination processing described later. In this case, the controller 31 accumulates the inventory information during the inventory period in the storage 32, reads the accumulated inventory information at the timing of the start of use of the lead-acid battery 2, and estimates the degradation amount at the start of use.

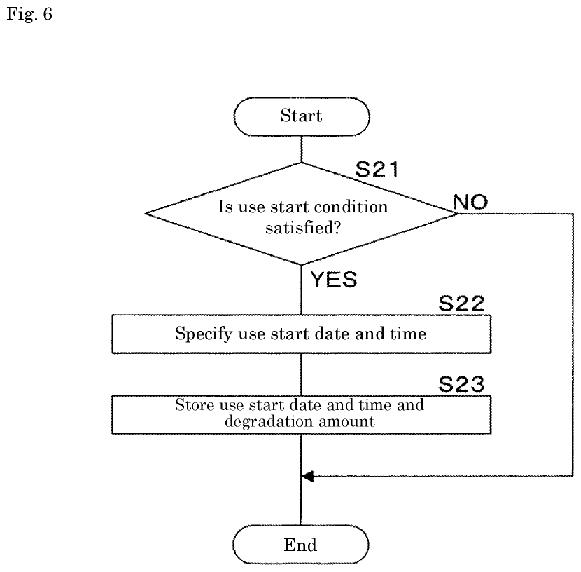

FIG. 6 is a flowchart illustrating an example of an acquisition processing procedure of the use start date and time. The controller 31 of the estimation device 3 executes the following processing according to the estimation program 321. The controller 31 may execute the following processing at predetermined timing, or may execute the following processing less than or equal to each time the measured data is acquired.

The controller 31 determines whether or not the use start condition is satisfied (step S21). For example, the use start condition is that the absolute value of the current value of the lead-acid battery 2 is greater than or equal to a predetermined value. The controller 31 determines whether the absolute value of the current value is greater than or equal to the predetermined value based on the latest measured data stored in the estimation data 322. When the lead-acid battery 2 is mounted on the vehicle to start the charge or the discharge, the current greater than or equal to the predetermined value is passed through the lead-acid battery 2. The controller 31 detects the start of use of the lead-acid battery 2 by detecting the current value.

For example, when it is determined that the use start condition is not satisfied because the absolute value of the current value is less than the predetermined value (NO in step S21), the controller 31 ends the processing.

When it is determined that the use start condition is satisfied as the absolute value of the current value is greater than or equal to the predetermined value (YES in step S21), the controller 31 specifies the time point at which the use start condition is satisfied as the time point at which the use of the lead-acid battery 2 is started, namely, the use start date and time (step S22). The controller 31 stores the specified use start date and time and the degradation amount corresponding to the use start date and time (time point at which the use start condition is satisfied) in the estimation data 322 of the storage 32 as use start time data while being associated with each other (step S23), and ends the series of processing.

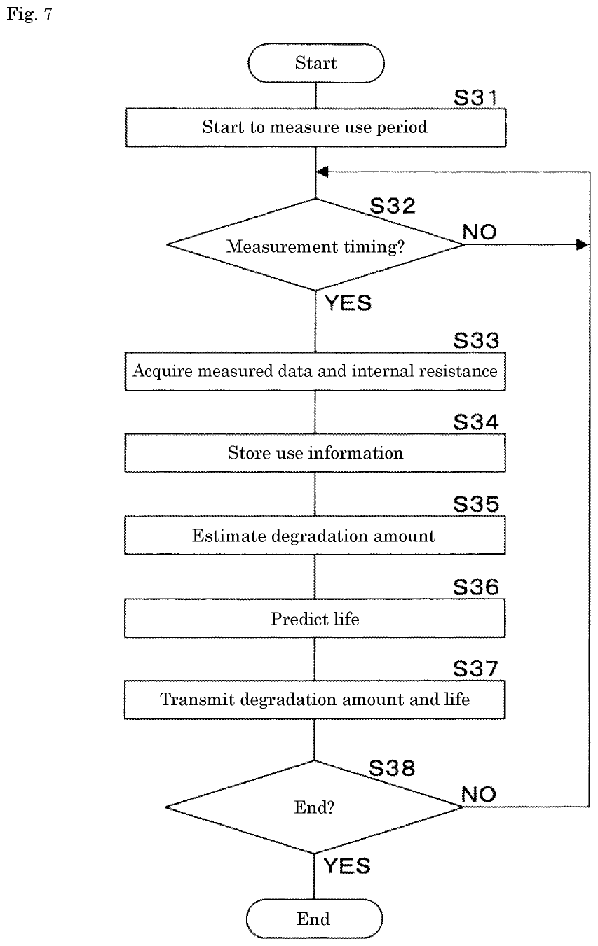

FIG. 7 is a flowchart illustrating an example of an estimation processing procedure of the degradation amount in the use period. The controller 31 of the estimation device 3 executes the following processing according to the estimation program 321.

The controller 31 starts to count (acquire) the elapsed period from the use start date and time, namely, the use period (step S31).

The controller 31 determines whether or not it is the measurement timing (step S32). Specifically, the controller 31 determines whether or not the measured data output from the various sensors 4 is acquired through the input/output unit 33. When it is determined that it is not the measurement timing (NO in step S32), the controller 31 waits until the measurement timing.

When it is determined that it is the measurement timing (YES in step S32), the controller 31 acquires the measured data including the temperature, the voltage value, and the current value of the lead-acid battery 2 through the input/output unit 33 and acquires the internal resistance of the lead-acid battery 2 (step S33). The controller 31 may acquire the measured data according to the output of the measured data by the various sensors 4 each time the new measured data is output from the various sensors 4 without determining whether or not it is the measurement timing. The controller 31 may acquire various types of measured data by receiving the measured data transmitted from the external device or the like through the communication unit 34. The controller 31 may acquire the internal resistance by reading the internal resistance of the lead-acid battery 2, the internal resistance being previously stored in the storage 32, or may acquire the internal resistance by communicating with the external device or the like to receive the internal resistance from the external device. The internal resistance is not newly acquired each time the measured data is acquired, but the internal resistance acquired at a predetermined timing may be continuously used.

The controller 31 associates the acquired measured data including the temperature, the voltage value, and the current value of the lead-acid battery 2, the internal resistance of the lead-acid battery 2, and the use period corresponding to the measured date and time of the measured data with each other, and stores them in the estimation data 322 of the storage 32 as use information (step S34).

The controller 31 estimates the degradation amount of the lead-acid battery 2 based on the acquired use information (step S35). The controller 31 calculates the degradation amount at the estimation target time point during the use period, the degradation amount being calculated by a mathematical model or the like using the use history. The controller 31 adds the degradation amount at the start of use of the lead-acid battery 2 to the calculated degradation amount to perform the correction, thereby calculating the final degradation amount at the estimation target time point during the use period.

The controller 31 predicts the life of the lead-acid battery 2 based on the calculated final degradation amount (step S36). The life prediction processing in step S36 may be omitted. The controller 31 transmits the estimated degradation amount and/or the predicted life of the lead-acid battery 2 to the external device (step S37). For example, the external device serving as a transmission destination may be the vehicle ECU 8.

The controller 31 determines whether or not to end (step S38). For example, the controller 31 may determine that the processing is ended by detecting that the lead-acid battery 2 is removed from the vehicle.

When determining not to end the processing (NO in step S38), the controller 31 returns the processing to step S32 to continue the estimation of the degradation amount. When determining to end the processing (YES in step S38), the controller 31 ends the series of processing.

According to the embodiment, the estimation accuracy of the degradation amount and the prediction accuracy of the life of the lead-acid battery 2 can be improved by taking into consideration the information on the inventory period that greatly affects the degradation amount of the lead-acid battery 2.

In the above specification, the degradation amount and the life of the lead-acid battery 2 are transmitted according to the acquisition of the measured data. Alternatively, for example, the controller 31 may calculate the degradation amount and the life of the lead-acid battery 2 as needed in response to a request received from the external device at arbitrary timing and transmit the calculated degradation amount and the life of the lead-acid battery 2 to the external device.

A lead-acid storage device according to one aspect of the present disclosure will be collectively described below.

(1) A lead-acid storage device including a lead-acid battery and an estimation device,
in which the estimation device includes:
an inventory information acquisition unit that acquires inventory information including an inventory period of the lead-acid battery;
a storage that stores the inventory information acquired by the inventory information acquisition unit; and
an estimation unit that estimates a degradation amount of the lead-acid battery based on the inventory information stored in the storage.

(2) In the above (1), the estimation unit may estimate the degradation amount based on a self-discharge amount or a stratified degree estimated from the inventory information.

(3) In the above (2), the inventory information may include a temperature related to the lead-acid battery in the inventory period, and
the estimation unit may correct the self-discharge amount or the stratified degree based on the temperature related to the lead-acid battery in the inventory period.

(4) In any one of the above (1) to (3), the lead-acid storage device may include
a use information acquisition unit that acquires use information including a use period of the lead-acid battery after start of use and a temperature related to the lead-acid battery during the use period, in which
the storage may store the use information acquired by the use information acquisition unit, and
the estimation unit may estimate the degradation amount based on the use information.

(5) In any one of the above (1) to (4), the estimation unit may predict a life of the lead-acid battery using the degradation amount.

(6) In any one of the above (1) to (5), the lead-acid storage device may include an output unit that outputs the degradation amount or the life of the lead-acid battery to an external device.

(7) In any one of (1) to (6), the lead-acid storage device may be used for a vehicle.

(8) An information processing method in which a computer executes processing including:
acquiring inventory information including an inventory period of a lead-acid battery;
storing the acquired inventory information; and
estimating a degradation amount of the lead-acid battery based on the stored inventory information.

(9) In the above (1), the degradation amount may be estimated based on a self-discharge amount or a stratified degree estimated from the inventory information.

(10) In the above (8) or (9), the inventory information may include a temperature related to the lead-acid battery in the inventory period, and the self-discharge amount or the stratified degree may be corrected based on the temperature related to the lead-acid battery in the inventory period.

(11) In any one of the above (8) to (10), use information including a use period of the lead-acid battery after the start of use and a temperature related to the lead-acid battery during the use period may be acquired, the acquired use information may be stored, and the degradation amount may be estimated based on the stored use information.

(12) In any one of the above (8) to (11), the life of the lead-acid battery may be predicted using the degradation amount.

(13) A computer program causing a computer to execute processing including:
acquiring inventory information including an inventory period of a lead-acid battery;
storing the acquired inventory information; and estimating a degradation amount of the lead-acid battery based on the stored inventory information.

(14) In the above (13), the degradation amount may be estimated based on a self-discharge amount or a stratified degree estimated from the inventory information.

(15) In the above (13) or (14), the inventory information may include a temperature related to the lead-acid battery in the inventory period, and the self-discharge amount or the stratified degree may be corrected based on the temperature related to the lead-acid battery in the inventory period.

(16) In any one of the above (13) to (15), use information including a use period of the lead-acid battery after the start of use and a temperature related to the lead-acid battery during the use period may be acquired, the acquired use information may be stored, and the degradation amount may be estimated based on the stored use information.

(17) In any one of the above (13) to (16), the life of the lead-acid battery may be predicted using the degradation amount.

The lead-acid battery device, the information processing method, and the computer program of the present disclosure can be applied to applications other than vehicles, and may be applied to industrial applications such as an emergency power supply.

It should be understood that the embodiment disclosed herein is illustrative in all points and not restrictive. The technical features described in the embodiment can be combined with each other, and the scope of the present invention is intended to include all modifications within the scope of the claims and the scope equivalent to the claims.

### DESCRIPTION OF REFERENCE SIGNS

1: lead-acid storage device
2: lead-acid battery
3: estimation device
31: controller
32: storage
33: input/output unit
34: communication unit
321: estimation program
322: estimation data
3A: recording medium

1. A lead-acid storage device comprising a lead-acid battery and an estimation device,
wherein the estimation device includes:
an inventory information acquisition unit that acquires inventory information including an inventory period of the lead-acid battery;
a storage that stores the inventory information acquired by the inventory information acquisition unit; and
an estimation unit that estimates a degradation amount of the lead-acid battery based on the inventory information stored in the storage.

2. The lead-acid storage device according to claim 1, wherein
the estimation unit estimates the degradation amount based on a self-discharge amount or a stratified degree estimated from the inventory information.

3. The lead-acid storage device according to claim 2, wherein
the inventory information includes a temperature related to the lead-acid battery in the inventory period, and
the estimation unit corrects the self-discharge amount or the stratified degree based on the temperature related to the lead-acid battery in the inventory period.

4. The lead-acid storage device according to claim 1, comprising
a use information acquisition unit that acquires use information including a use period of the lead-acid battery after start of use and a temperature related to the lead-acid battery during the use period, wherein
the storage stores the use information acquired by the use information acquisition unit, and
the estimation unit estimates the degradation amount based on the use information.

5. The lead-acid storage device according to claim 1, wherein
the estimation unit predicts a life of the lead-acid battery using the degradation amount.

6. The lead-acid storage device according to claim 1, comprising
an output unit that outputs the degradation amount or the life of the lead-acid battery to an external device.

7. The lead-acid storage device according to claim 1, wherein
the lead-acid storage device is used for a vehicle.

8. An information processing method in which a computer executes processing comprising:
acquiring inventory information including an inventory period of a lead-acid battery;
storing the acquired inventory information; and
estimating a degradation amount of the lead-acid battery based on the stored inventory information.

9. A computer program causing a computer to execute processing comprising:
acquiring inventory information including an inventory period of a lead-acid battery;
storing the acquired inventory information; and
estimating a degradation amount of the lead-acid battery based on the stored inventory information.
